(19) United States
(12) Patent Application Publication
(10) Pub. No.: US 2026/0229399 A1
(43) Pub. Date: Aug. 6, 2026

(54) INDUCTOR WIRING STRUCTURE AND MAGNETIC COMPONENT

(71) Applicant: Lite-On Technology Corporation, Taipei (TW)

(72) Inventors: Kai-De Chen, Taipei (TW); Yong-Long Syu, Taipei (TW); Cheng-Wei Tseng, Taipei (TW); Dung Ruen Ho, Taipei (TW); Chen Chen, Taipei (TW)

(73) Assignee: Lite-On Technology Corporation, Taipei (TW)

(21) Appl. No.: 19/201,906

(22) Filed: May 7, 2025

Related U.S. Application Data
(60) Provisional application No. 63/753,460, filed on Feb. 4, 2025.

(30) Foreign Application Priority Data
Apr. 15, 2025 (CN) 202520707910.7

(51) Int. Cl. H01F 27/30; H01F 27/24; H05K 1/18

(52) U.S. Cl. CPC H01F 27/306; H01F 27/24; H05K 1/18

(57) ABSTRACT

An inductor wiring structure includes an inductor wiring and a core member. The inductor wiring has input and output ends, and includes a first wiring connected to the input end and a second wiring connected to the output end. The core member is magnetically coupled to the inductor wiring, and the core member includes a base, a center column protruded beyond the base, and two side columns. A first space and a second space are respectively between the center column and the two side columns, the first wiring at least passes through the first space to surround the center column, and the second wiring passes through the second space to surround the center column, wherein a number of times the inductor wiring passes through the first space is equal to a number of times the inductor wiring passes through the second space. A magnetic component is also provided.

### CROSS-REFERENCE TO RELATED APPLICATION

This application claims the priority benefits of U.S. provisional application serial no. 63/753,460, filed on February 4, 2025, and China application serial no. 202520707910.7, filed on April 15, 2025. The entirety of each of the above-mentioned patent applications is hereby incorporated by reference herein and made a part of this specification.

### BACKGROUND OF THE INVENTION

### Field of the Invention

The invention relates to an inductor winding, and in particular to an inductor wiring structure and a magnetic component.

### Description of Related Art

With the rapid development of the information industry, server power supplies have played an indispensable role, wherein the circuit architecture is, for example, an LLC resonant converter, a buck converter, a series capacitor buck converter (SCB), etc.

For example, a resonant converter generally includes magnetic components such as resonant inductors and transformers. These magnetic components are generally composed of a coil and a core. How to effectively reduce inductor winding loss and avoid core flux imbalance, and effectively reduce overall volume, is one of the topics to be studied by those skilled in the art.

### SUMMARY OF THE INVENTION

The invention provides an inductor wiring structure effectively reducing inductor winding loss and avoiding core flux imbalance, and effectively reducing overall volume.

An inductor wiring structure of the invention includes an inductor wiring and a core member. The inductor wiring has an input end and an output end, and includes a first wiring connected to the input end and a second wiring connected to the output end. The core member is magnetically coupled to the inductor wiring, and the core member includes a base, a center column protruded beyond the base, and two side columns. There is a first space and a second space respectively between the center column and the two side columns, the first wiring at least passes through the first space to surround the center column, and the second wiring passes through the second space to surround the center column, wherein a number of times the inductor wiring passes through the first space is equal to a number of times the inductor wiring passes through the second space.

The inductor wiring structure of the invention includes an inductor wiring, a core member, and a circuit board. The inductor wiring has an input end and an output end, and includes a first wiring connected to the input end and a second wiring connected to the output end. The core member is magnetically coupled to the inductor wiring, and the core member includes a base, a center column protruded beyond the base, and two side columns. There is a first space and a second space respectively between the center column and the two side columns, the first wiring at least passes through the first space to surround the center column, and the second wiring passes through the second space to surround the center column, wherein a number of times the inductor wiring passes through the first space is equal to a number of times the inductor wiring passes through the second space. The inductor wiring is formed at the circuit board, and the center column passes through a through hole of the circuit board.

A magnetic component of the invention includes a wiring and a core member. The wiring has a first wiring and a second wiring. The core member includes a base, an upper cover, a center column, a first side column, and a second side column, wherein the center column, the first side column, and the second side column are disposed between the base and the upper cover, and the center column is located between the first side column and the second side column. The first wiring passes through between the center column and the first side column, the second wiring passes through between the center column and the second side column, and the first wiring and the second wiring are not in contact with each other.

In one embodiment of the invention, a cross-sectional area of the center column is greater than a cross-sectional area of each of the side columns.

In an embodiment of the invention, the first wiring has a first end away from the input end, and the second wiring has a second end away from the output end, the input end and the output end are located at a side of the core component, and the first end and the second end are located at another side of the core component.

In an embodiment of the invention, the center column includes an upper sidewall and a lower sidewall symmetrically divided by a center of the center column, the upper sidewall corresponds to the first space, the lower sidewall corresponds to the second space, there is a first winding segment between the input end and the first end, the first winding segment is wound around the upper sidewall of the center column, there is a second winding segment between the output end and the second end, and the second winding segment is wound around the lower sidewall of the center column.

In an embodiment of the invention, the center column includes an upper sidewall and a lower sidewall symmetrically divided by a center of the center column, the upper sidewall corresponds to the first space, the lower sidewall corresponds to the second space, there is a first winding segment between the input end and the first end, the first winding segment is wound around the upper sidewall and the lower sidewall of the center column, a number of times the first winding segment passes through the upper sidewall is N, a number of times the first winding segment passes through the lower sidewall is N- 1, there is a second winding segment between the output end and the second end, the second winding segment is wound around the lower sidewall of the center column, and a number of times the second winding segment passes through the lower sidewall is 1.

In an embodiment of the invention, the first end and the second end are used to connect a transformer.

In an embodiment of the invention, the two side columns are arranged in a first direction, and an extending direction of a primary side coil of the transformer and an extending direction of a secondary side coil of the transformer are parallel to the first direction.

In an embodiment of the invention, the circuit board is a single-layer board, the center column includes an upper sidewall and a lower sidewall symmetrically divided by a center of the center column, the upper sidewall corresponds to the first space, the lower sidewall corresponds to the second space, there is a first winding segment between the input end and the first end, the first winding segment is wound around the upper sidewall of the center column, there is a second winding segment between the output end and the second end, and the second winding segment is wound around the lower sidewall of the center column.

In an embodiment of the invention, the circuit board is a multi-layer board, the center column includes an upper sidewall and a lower sidewall symmetrically divided by a center of the center column, the upper sidewall corresponds to the first space, the lower sidewall corresponds to the second space, there is a first winding segment between the input end and the first end, the first winding segment is wound around the upper sidewall and the lower sidewall of the center column, a number of times the first winding segment passes through the upper sidewall is N, a number of times the first winding segment passes through the lower sidewall is N-1, there is a second winding segment between the output end and the second end, the second winding segment is wound around the lower sidewall of the center column, and a number of times the second winding segment passes through the lower sidewall is 1.

In an embodiment of the invention, the circuit board includes a first layer board and a second layer board, a conductive structure is provided between the first layer board and the second layer board, the first winding segment includes a first section and a second section, the first section is located at the first layer board, the second section is located at the second layer board, the first section completely surrounds the upper sidewall and the lower sidewall of the center column and is electrically connected to the second section via the conductive structure, and the second section is wound around the upper sidewall.

In an embodiment of the invention, the second winding segment is located at the second layer board.

In an embodiment of the invention, the magnetic component further includes a third wiring and a conductive structure. The third wiring passes through between the center column and the first side column and passes through between the center column and the second side column. The conductive structure is connected to the third wiring and the first wiring.

In an embodiment of the invention, there is a first spacing, a second spacing, and a third spacing between the first wiring and the second wiring, the first spacing is greater than the second spacing, and the second spacing is greater than or equal to the third spacing.

Based on the above, in the inductor wiring structure of the invention, there is a first space and a second space respectively between the center column and the two side columns, the first wiring at least passes through the first space to surround the center column, and the second wiring only passes through the second space to surround the center column. Thereby, the total number of windings formed by the inductor wiring at the first space is equal to the total number of windings formed by the inductor wiring at the second space, to achieve maintaining a relatively uniform flux distribution of the magnetic core and effectively reducing the winding loss of the copper wire.

In order to make the aforementioned features and advantages of the disclosure more comprehensible, embodiments accompanied with figures are described in detail below.

### BRIEF DESCRIPTION OF THE DRAWINGS

FIG. 1 is a schematic top view of an inductor wiring structure of an embodiment of the invention.

FIG. 2 is a circuit diagram of the inductor wiring structure of FIG. 1.

FIG. 3 is a schematic diagram of an application architecture of the inductor wiring structure of FIG. 2.

FIG. 4A to FIG. 4D are circuit diagrams of the inductor wiring structure of FIG. 3 in different application architectures.

FIG. 5A is a schematic three-dimensional diagram of a magnetic component of an embodiment of the invention.

FIG. 5B is an exploded view of the magnetic component of FIG. 5A.

FIG. 5C is a schematic diagram of the path of the inductor wiring on the circuit board of FIG. 5A.

FIG. 5C' is a schematic diagram of a path of an inductor wiring on a circuit board of another embodiment of the invention.

FIG. 5D is a schematic top view of the inductor wiring on the core member of FIG. 5A.

FIG. 6A is a schematic three-dimensional diagram of a magnetic component of an embodiment of the invention.

FIG. 6B is an exploded view of the magnetic component of FIG. 6A.

FIG. 6C is a schematic diagram of the path of the inductor wiring on the circuit board of FIG. 6A.

FIG. 6D is a schematic top view of the inductor wiring on the core member of FIG. 6A.

FIG. 7A and FIG. 7B are three-dimensional schematic diagrams of core members of a plurality of embodiments of the invention.

FIG. 8 and FIG. 9 are three-dimensional schematic diagrams of inductor wiring structures of a plurality of embodiments of the invention.

### DESCRIPTION OF THE EMBODIMENTS

In general, the inductor winding, for example, completes one turn before going to the next layer or connecting to the next component, so that the inductance may reach the designed value and the flux distribution of the inductor core may be kept uniform. However, there is no other way to reduce copper wire losses with one turn of the inductor wiring. The inductor wiring structure of the invention may solve the above issue.

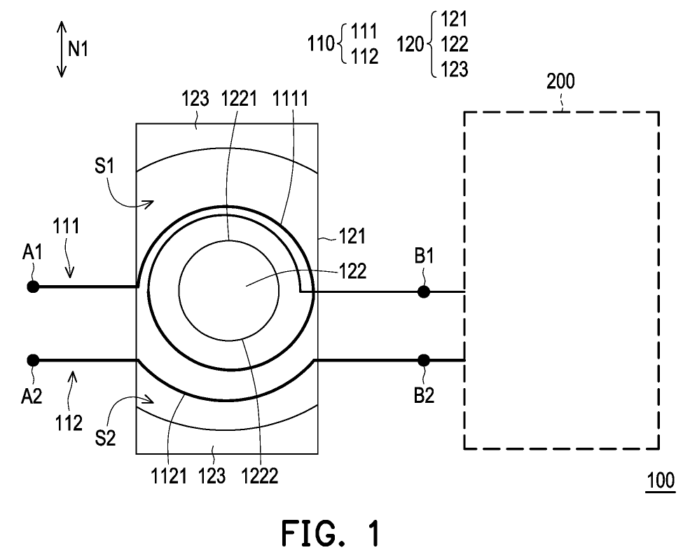

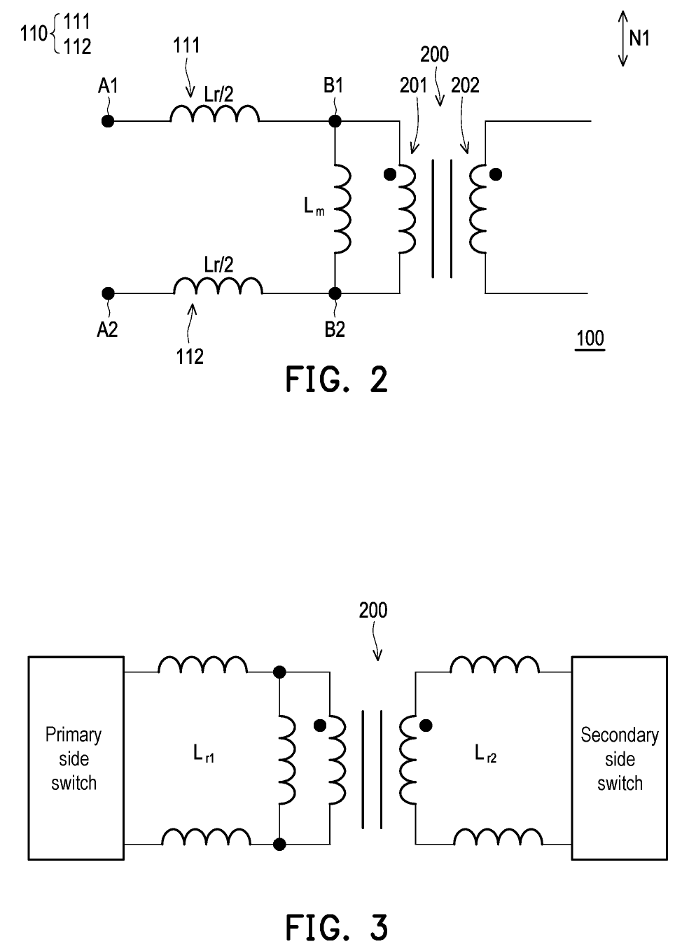

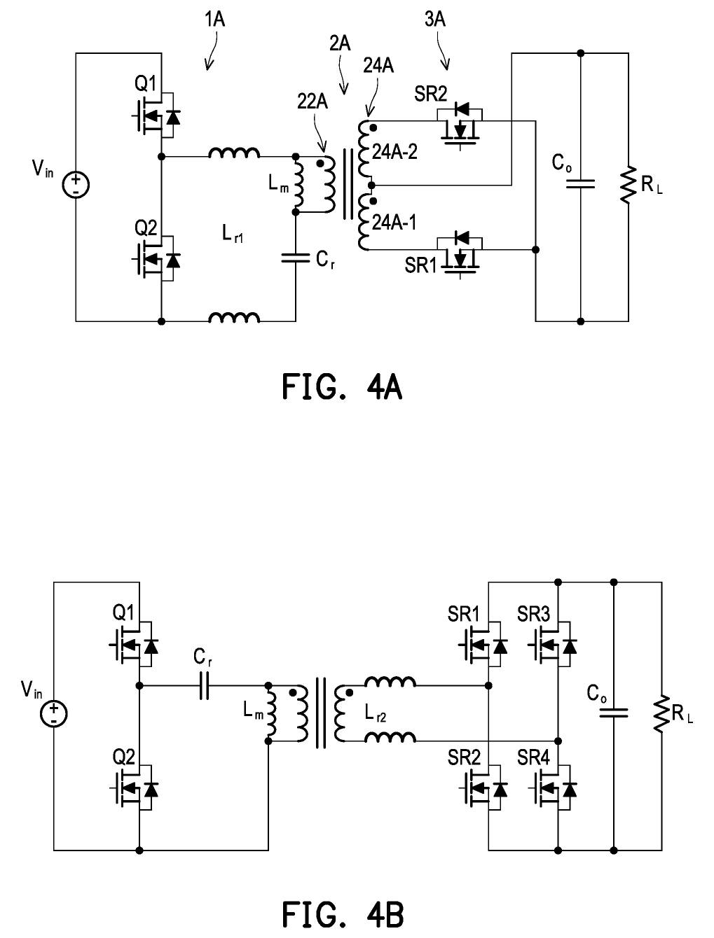

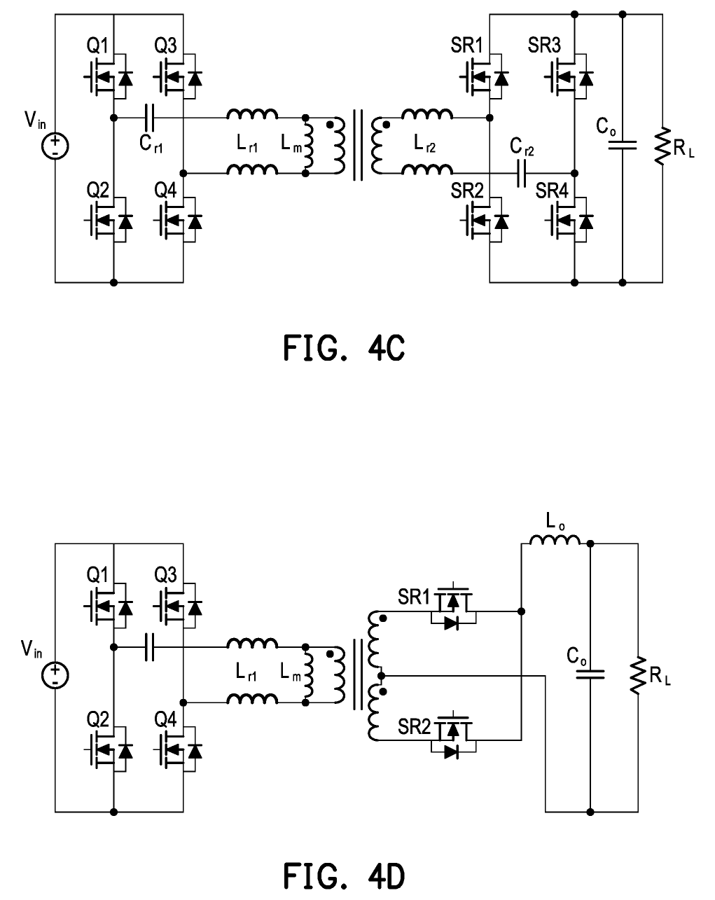

FIG. 1 is a schematic top view of an inductor wiring structure of an embodiment of the invention. FIG. 2 is a circuit diagram of the inductor wiring structure of FIG. 1. FIG. 3 is a schematic diagram of an application architecture of the inductor wiring structure of FIG. 2. FIG. 4A to FIG. 4D are circuit diagrams of the inductor wiring structure of FIG. 3 in different application architectures. It should be noted that FIG. 1 merely schematically illustrates the relative positions of each component, and the actual size ratios thereof are not limited thereto.

Please refer to FIG. 1 and FIG. 2. An inductor wiring structure 100 of the present embodiment includes an inductor wiring 110 and a core member 120. The inductor wiring 110 has an input end Al and an output end A2, and includes a first wiring 111 connected to the input end Al and a second wiring 112 connected to the output end A2.

In the present embodiment, the first wiring 111 has a first end B1 away from the input end Al, and the second wiring 112 has a second end B2 away from the output end A2. The input end Al and the output end A2 are located at a side of the core component 120, and the first end B1 and the second end B2 are located at another side of the core component 120.

In an embodiment, the cross-sectional area of the center column 122 is greater than the cross-sectional area of each of the side columns 123, but the invention is not limited thereto.

In the present embodiment, the core member 120 is magnetically coupled to the inductor wiring 110. The core member 120 includes a base 121, a center column 122 protruded beyond the base 121, and two side columns 123. There is a first space S1 and a second space S2 respectively between the center column 122 and the two side columns 123.

In the present embodiment, the center column 122 includes an upper sidewall 1221 and a lower sidewall 1222 symmetrically divided around the center of the center column 122. The upper sidewall 1221 corresponds to the first space Si, and the lower sidewall 1222 corresponds to the second space S2. Specifically, the first space S1 is defined between the upper sidewall 1221 and the adjacent side column 123, and the second space S2 is defined between the lower sidewall 1222 and the adjacent side column 123, but the invention is not limited thereto.

In the present embodiment, there is a first winding segment 1111 between the input end Al and the first end B l. The first winding segment 1111 is wound around the upper sidewall 1221 and the lower sidewall 1222 of the center column 122. The number of times the first winding segment 1111 passes through the upper sidewall 1221 is N, and the number of times the first winding segment 1111 passes through the lower sidewall 1222 is N-1. Here, N is 2, but the invention is not limited thereto. In the present embodiment, there is a second winding segment 1121 between the output end A2 and the second end B2. The second winding segment 1121 is wound around the lower sidewall 1222 of the center column 122. The number of times the second winding segment 1121 passes through the lower sidewall 1222 is 1. Thereby, the total number of windings formed by the inductor wiring 110 at the first space S1 is equal to the total number of windings formed by the inductor wiring 110 at the second space S2, to achieve maintaining a relatively uniform flux distribution of the magnetic core and effectively reducing the winding loss of the copper wire.

In detail, in the present embodiment, the first wiring 111 is extended from left to right into the core member 120 along a direction perpendicular to a first direction N1 and passes through the first space S1 to circle around the upper half of the center column 122 in a clockwise direction and then enters the second space S2 downward to circle around the lower half of the center column 122 in a clockwise direction, and completes one turn around the entire center column 122. Then, the first wiring 111 returns to the first space S1 to circle around the upper half of the center column 122 in a clockwise direction. Lastly, the end of the first wiring 111 is moved to the right out of the core member 120, and the end thereof serves as the first end Bl. Thus, the first wiring 111 is wound twice (forming two layers) at the upper side of the center column 122, that is, at the first space Si. The first wiring 111 is wound once (forming one layer) at the lower side of the center column 122, that is, at the second space S2. Here, the upper half of the center column 122 refers to, for example, a position corresponding to the upper sidewall 1221, and the lower half of the center column 122 refers to, for example, a position corresponding to the lower sidewall 1222, but the invention is not limited thereto.

Similarly, in the present embodiment, the second wiring 112 is extended from left to right into the core member 120 and passes through the second space S2 and surrounds the lower half of the center column 122 in a counterclockwise direction. Lastly, the end of the second wiring 112 is moved rightward out of the core member 120, and the end thereof serves as the second end B2. Thus, the second wiring 112 is wound once (forming one layer) at the lower side of the center column 122, that is, at the second space S2.

Therefore, the total number of windings formed by the inductor wiring 110 at the first space S1 is 2, and the total number of windings formed by the inductor wiring 110 at the second space S2 is also 2. In this way, the total number of windings formed by the inductor wiring 110 at the first space S1 is equal to the total number of windings formed by the inductor wiring 110 at the second space S2, to achieve maintaining a relatively uniform flux distribution of the magnetic core and effectively reducing the winding loss of the copper wire.

In the above embodiment, the total number of turns of the inductor wiring 110 is 2, but the invention is not limited thereto. In other embodiments, the total number of turns of the inductor winding is 1, and the first wiring passes through the first space to be wound once at the first space (forming 1 layer). The second wiring only passes through the second space and is wound once at the second space (forming one layer). Therefore, the total number of windings formed by the inductor wiring at the first space is 1, and the total number of windings formed by the inductor wiring at the second space is also 1. Thereby, the total number of windings formed by the inductor wiring at the first space is equal to the total number of windings formed by the inductor wiring at the second space, to achieve maintaining a relatively uniform flux distribution of the magnetic core, avoiding core flux imbalance, effectively reducing the winding loss of the copper wire, and effectively reducing overall volume.

Furthermore, in an embodiment, the first end B1 and the second end B2 are used to connect a transformer 200, but the invention is not limited thereto. The two side columns 123 are arranged in the first direction N1, and an extending direction of a primary side coil 201 of the transformer 200 and an extending direction of a secondary side coil 202 of the transformer 200 are parallel to the first direction N1.

Here, the inductor wiring structure 100 is applicable to an architecture including a resonant inductor and a transformer. The first wiring 111 and the second wiring 112 both pass through the core member 120, and may make the current loop present a closed loop through the primary or secondary side switch and the transformer, so that the resonant inductor generates flux and is operated normally. In the present embodiment, Lᵣ is the resonant inductor, and Lm is the magnetizing inductor. Under the above configuration, after the resonant inductor has a partial number of turns, the resonant inductor is first connected to the transformer 200, and lastly the resonant inductor is pulled back to make up the remaining number of turns, so that the overall space utilization rate of the inductor wiring structure 100 is good, the resonant inductor is wound around the center column 122 for a full n turns, the core flux is balanced, and no additional circuit board space is needed.

Please refer to FIG. 3, Lᵣ₁ is the primary side resonant inductor, and Lᵣ₂ is the secondary side resonant inductor. That is, the resonant inductor of the present embodiment may be placed at the primary side or the secondary side for resonant application or to assist the switch in zero-voltage switching, which is called a resonant inductor.

Furthermore, the application architecture of the inductor wiring structure 100 may be the LLC resonant converter of FIG. 4A, the CCL resonant converter of FIG. 4B, the CLLC resonant converter of FIG. 4C, or the full-bridge phase-shift converter of FIG. 4D, and the invention is not limited thereto.

Taking FIG. 4A as an example, the LLC resonant converter includes a primary side circuit lA, a transformer 2A, and a secondary side circuit 3A. The primary side circuit lA includes two power switches Q1 and Q2 connected in series. The secondary side circuit 3A includes a rectifier circuit. A rectifier circuit 32 includes one rectifier switch SR1 and SR2. A secondary side coil 24A of the transformer 2A includes a first coil 24A-1 and a second coil 24A-2. In an embodiment, the LLC resonant converter of FIG. 4A may control the on or off of the rectifier switches SR1 and SR2 via a controller (not shown) so that the first coil 24A-1 and the second coil 24A-2 are respectively coupled to a primary side coil 22A. Here, the circuit structures of the primary side circuit lA and the secondary side circuit 3A are only schematically illustrated, and the invention is not limited thereto. In addition, in an embodiment, the transformer 2A may be one as shown in FIG. 4A, but the invention is not limited thereto. In another embodiment, one set or more of transformers 2A may be included, but the invention is not limited thereto.

Other embodiments are listed below for illustration. It should be mentioned that, the embodiments below use the same reference numerals and portions of the content from previous embodiments. Specifically, the same reference numerals are used to represent the same or similar components, and the descriptions for the same techniques are omitted. The omitted portions are as described in the embodiments above and are not repeated in the following embodiment.

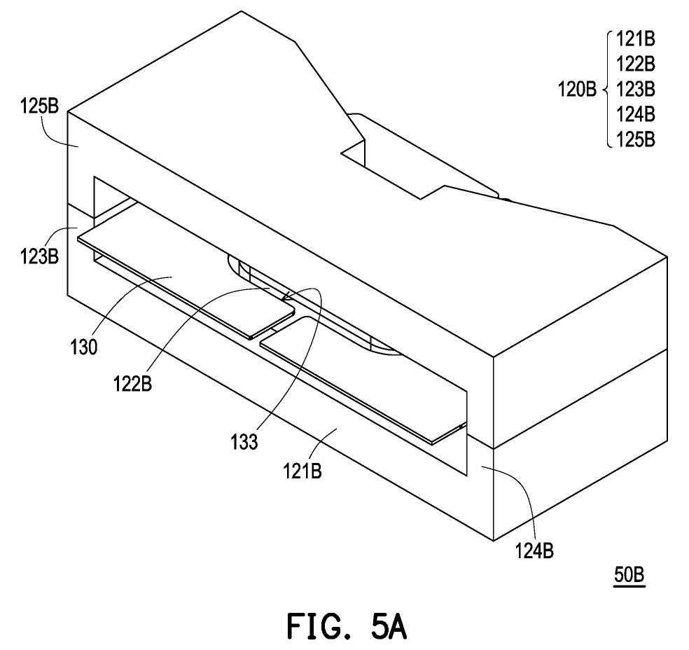

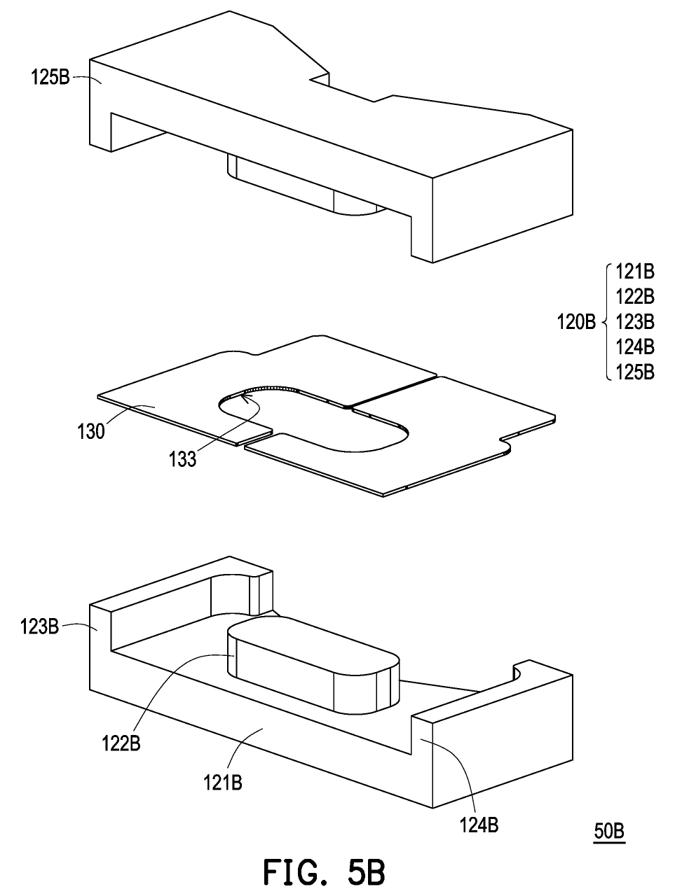

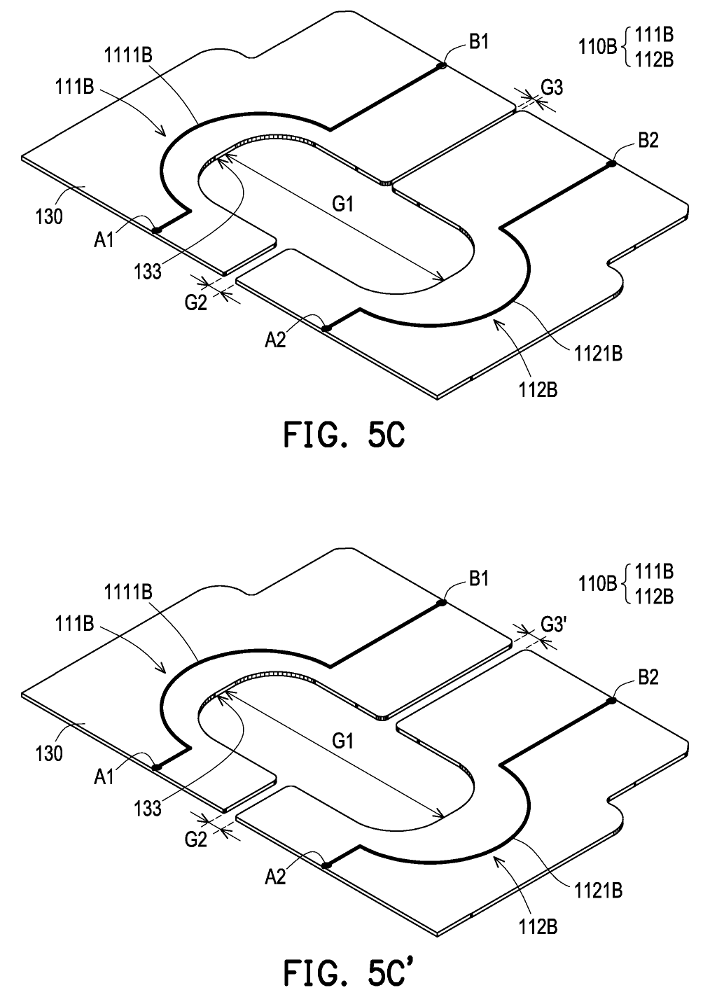

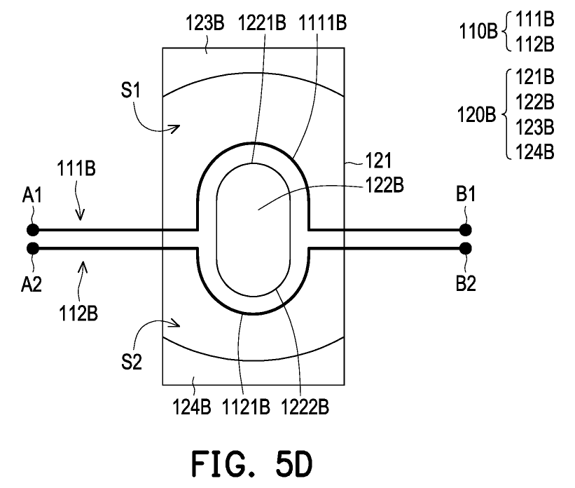

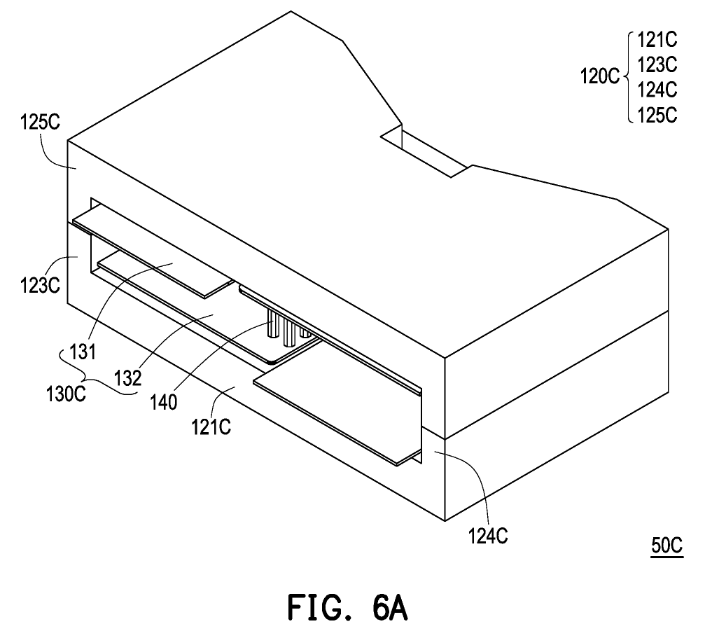

FIG. 5A is a schematic three-dimensional diagram of a magnetic component of an embodiment of the invention. FIG. 5B is an exploded view of the magnetic component of FIG. 5A. FIG. 5C is a schematic diagram of the path of the inductor wiring on the circuit board of FIG. 5A. FIG. 5D is a schematic top view of the inductor wiring on the core member of FIG. 5A. It should be noted that the wiring paths are schematically depicted with thick lines in FIG. 5C, and the circuit board is omitted in FIG. 5D for the convenience of description. Please refer to FIG. 5A to FIG. 5D, a magnetic component SOB of the present embodiment includes a core member 120B. The core member 120B includes a base 121B, an upper cover 125B, a center column 122B, a first side column 123B, and a second side column 124B. The center column 122B, the first side column 123B, and the second side column 124B are disposed between the base 121B and the upper cover 125B, and the center column 122B is located between the first side column 123B and the second side column 124B. In an embodiment, the center column 122B of the core member 120B passes through a through hole 133 of the circuit board 130. As shown in FIG. 5C, the magnetic component 50B includes a wiring lOB. The wiring lOB is, for example, a planar winding formed at a printed circuit board (PCB) 130, but the invention is not limited thereto.

In the present embodiment, the circuit board 130 is a single-layer board. In other words, the magnetic component SOB is designed as a planar inductor by means of PCB wiring, but the invention is not limited thereto.

Please refer to FIG. 5C and FIG. 5D. In the present embodiment, a first wiring 111B passes through between the center column 122B and the first side column 123B, and a second wiring 112B passes through between the center column 122B and the second side column 123B. Specifically, a first winding segment 111 lB of the first wiring 111B is wound around an upper sidewall 1221B of the center column 122B, and a second winding segment 1121B of the second wiring 112B is wound around a lower sidewall 1222B of the center column 122B. That is, the first wiring 111B passes through the first space S1 to be wound once at the first space S1 (forming one layer). The second wiring 112B only passes through the second space S2 and is wound once at the second space S2 (forming one layer). Therefore, the total number of windings formed by the inductor wiring 110B at the first space S1 is 1, and the total number of windings formed by the inductor wiring 110B at the second space S2 is also 1. Thereby, the total number of windings formed by the inductor wiring 100B at the first space S1 is equal to the total number of windings formed by the inductor wiring lOB at the second space S2, to achieve maintaining a relatively uniform flux distribution of the magnetic core, avoiding core flux imbalance, effectively reducing the winding loss of the copper wire, and effectively reducing overall volume.

As shown in FIG. 5C, in the present embodiment, the first wiring 111B and the second wiring 112B are not in contact with each other. The term "not in contact" means that the first wiring 111B and the second wiring 112B do not have any structural physical contact. Therefore, there is a spacing between the first wiring 111B and the second wiring 112B. Here, the minimum spacing between the first wiring 111B and the second wiring 112B is greater than zero.

For example, in the present embodiment, there is a first spacing G1, a second spacing G2, and a third spacing G3 between the first wiring 111B and the second wiring 112B. Here, the second spacing G2 is defined as a gap between the input end Al and the output end A2. The first spacing G1 is defined as a gap between the first winding segment 111lB and the second winding segment 1121B. The third spacing G3 is defined as a gap between the first end B1 and the second end B2.

In the present embodiment, the first spacing G1 is greater than the second spacing G2, and the second spacing G2 is greater than the third spacing G3, but the invention is not limited thereto. FIG. 5C' is a schematic diagram of a path of an inductor wiring on a circuit board of another embodiment of the invention. Referring to FIG. 5C', in an embodiment, the first spacing G1 is greater than the second spacing G2, and the second spacing G2 is equal to a third spacing G3', but the invention is not limited thereto.

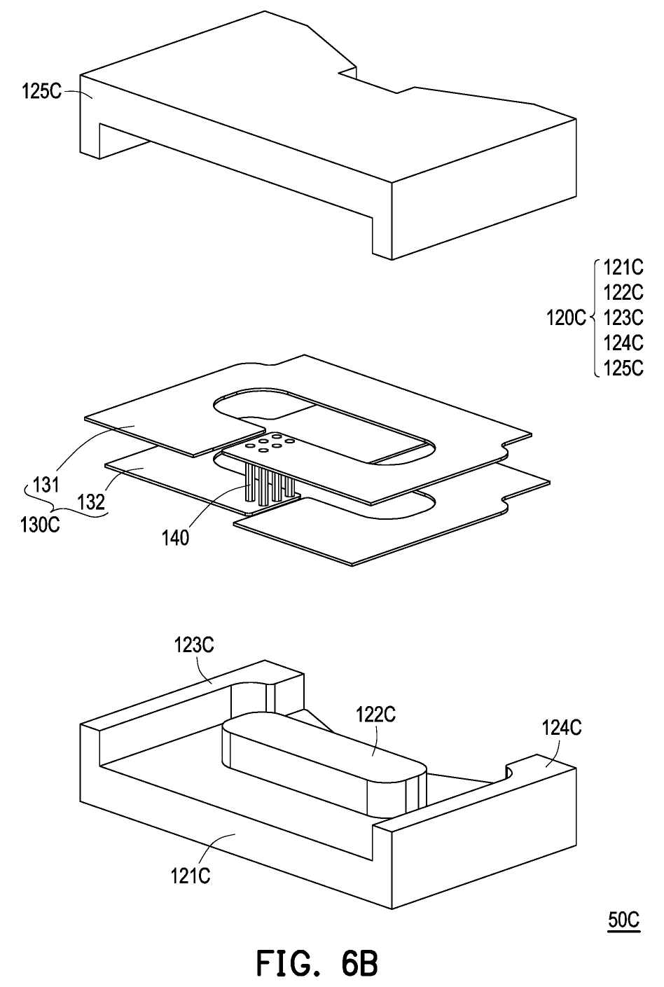

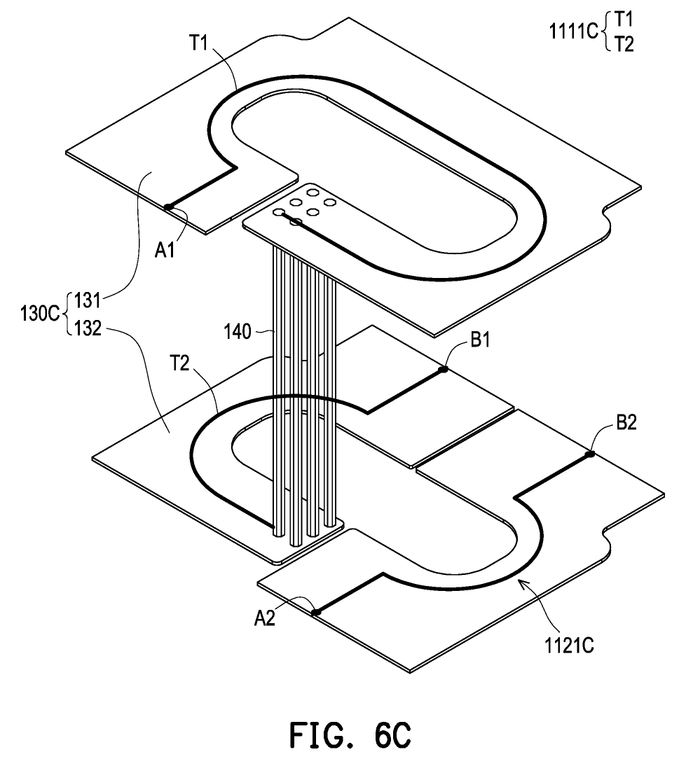

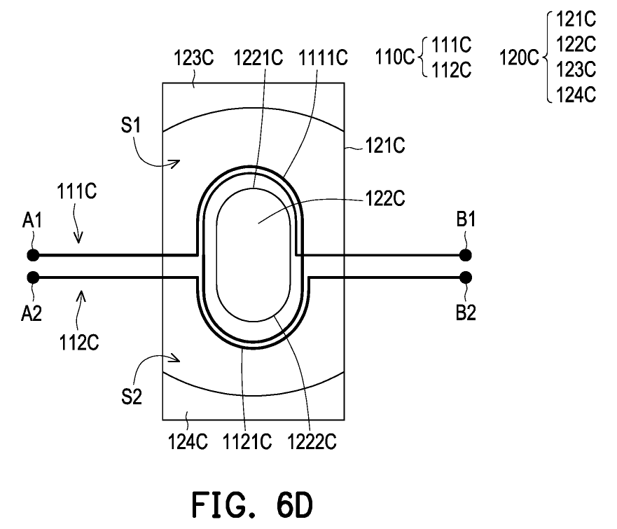

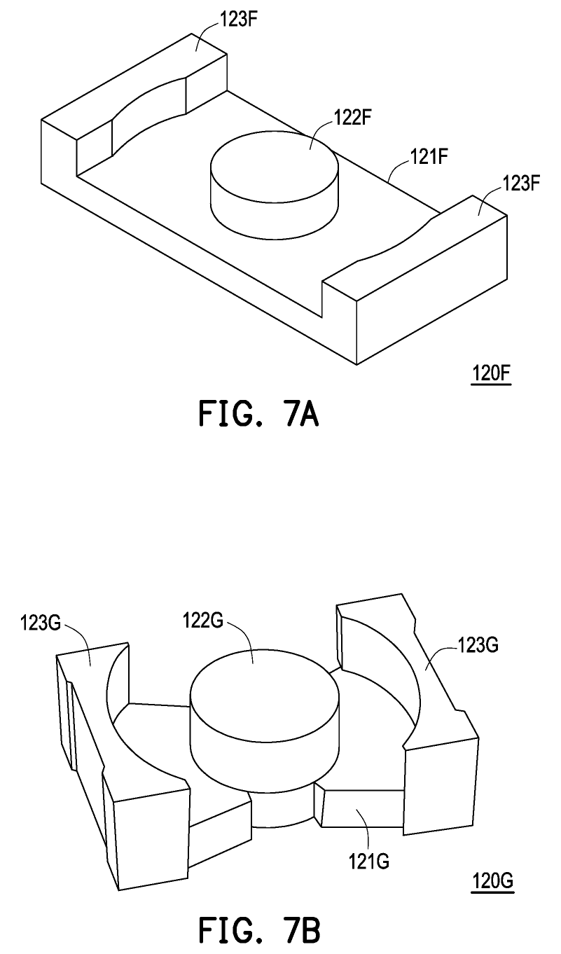

FIG. 6A is a schematic three-dimensional diagram of a magnetic component of an embodiment of the invention. FIG. 6B is an exploded view of the magnetic component of FIG. 6A. Please refer to FIG. 6A and FIG. 6B. In the present embodiment, a magnetic component 50C is slightly different from the magnetic component 50B of FIG. 5A. The main differences are: a circuit board 130C is a multi- layer board, and the magnetic component 50C further includes a conductive structure 140.

In the present embodiment, a core member 120C includes a base 121C, an upper cover 125C, a center column 122C, a first side column 123C, and a second side column 124C. The center column 122C, the first side column 123C, and the second side column 124C are disposed between the base 121C and the upper cover 125C, and the center column 122C is located between the first side column 123C and the second side column 124C.

In the present embodiment, the circuit board 130C includes a first layer board 131 and a second layer board 132, and the conductive structure 140 is provided between the first layer board 131 and the second layer board 132.

FIG. 6C is a schematic diagram of the path of the inductor wiring on the circuit board of FIG. 6A. FIG. 6D is a schematic top view of the inductor wiring on the core member of FIG. 6A. It should be noted that the wiring paths are schematically depicted with thick lines in FIG. 6C, and the circuit board is omitted in FIG. 6D for the convenience of description. Here, the size of the conductive structure is only schematically illustrated, and the actual size thereof is not limited thereto.

Please refer to FIG. 6C and FIG. 6D. In the present embodiment, a first winding segment 1111C includes a first section T1 and a second section T2. The first section T1 is located at the first layer board 131, and the second section T2 is located at the second layer board 132. The first section T1 completely surrounds an upper sidewall 1221C and a lower sidewall 1222C of the center column 122C and is electrically connected to the second section T2 via the conductive structure 140. The second section T2 is wrapped around the upper sidewall 1221C. A second winding segment 1121C is located at the second layer board 132. The second section T2 is not in contact with the second winding segment 1121C. The non-contact means that the second section T2 has no structural physical contact with the second winding segment 1121C. Therefore, there is a spacing between the second section T2 and the second winding segment 1121C. Here, the minimum spacing between the second section T2 and the second winding segment 1121C is greater than zero. Furthermore, the first layer board 131 where the first section T1 is located may be understood as a wiring passing between the center column 122C and the first side column 123C and passing between the center column 122C and the second side column 124C. Similarly, the portion of the second layer board 132 corresponding to the second section T2 may be understood as a wiring passing between the center column 122C and the first side column 123C. The portion of the second layer board 132 corresponding to the second winding segment 1121C may be understood as a wiring passing between the center column 122C and the second side column 124C.

In the present embodiment, the number of times the first winding segment 1111C passes through the upper sidewall 1221C is 2, and the number of times the first winding segment 1111 C passes through the lower sidewall 1222C is 1, but the invention is not limited thereto. In the present embodiment, the number of times the second winding segment 1121C passes through the lower sidewall 1222C is 1. Thereby, the total number of windings formed by the inductor wiring 100 at the first space S1 is equal to the total number of windings formed by the inductor wiring 110 at the second space S2, to achieve maintaining a relatively uniform flux distribution of the magnetic core, avoiding core flux imbalance, effectively reducing the winding loss of the copper wire, and effectively reducing overall volume.

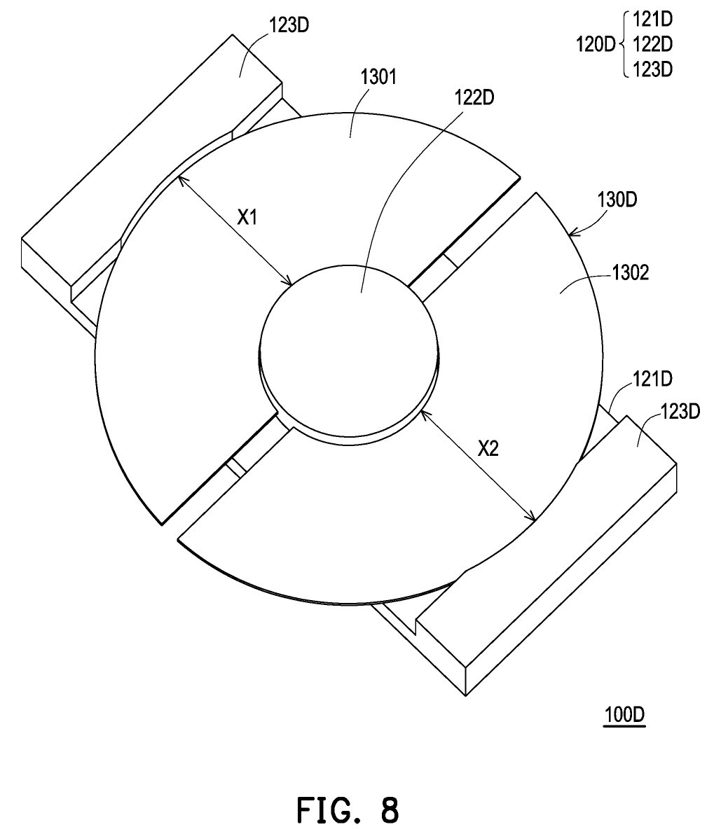

In addition, in FIG. 5B and FIG. 5C, the center columns 122B and 122C of the core members 120B and 120C are long oval columns, but the invention is not limited thereto. FIG. 7A and FIG. 7B are three-dimensional schematic diagrams of core members of a plurality of embodiments of the invention. A core member 120F of FIG. 7A includes a base 121F, a center column 122F protruded beyond the base 121F, and two side columns 123F. Here, the center column 122F is a cylinder, and the side columns 123F have arc-shaped notches, but the invention is not limited thereto. A core member 120G of FIG. 7B includes a base 121G, a center column 122G protruded beyond the base 121G, and two side columns 123G. Here, the base 121G is two opposite fan-shaped structures, and the side columns 123G have notches corresponding to the outer contour of the center column 122G, but the invention is not limited thereto.

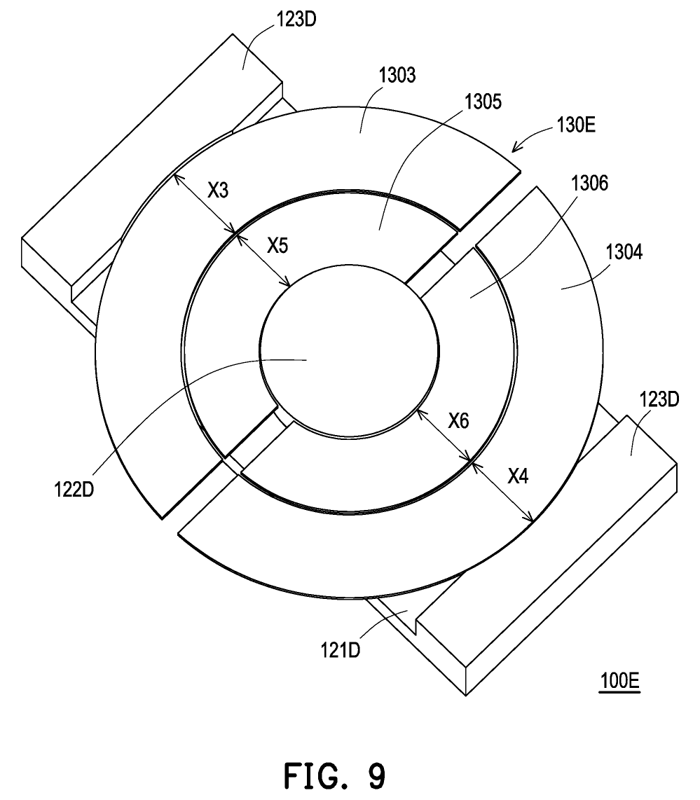

FIG. 8 and FIG. 9 are three-dimensional schematic diagrams of inductor wiring structures of a plurality of embodiments of the invention. It should be noted that FIG. 8 and FIG. 9 are merely schematic simplistic illustrations of the relative positions of the components, and the actual size ratios thereof are not limited thereto. Please refer to FIG. 8 first. A core member 120D of an inductor wiring structure 100D includes a base 121D, a center column 122D protruded beyond the base 121D, and two side columns 123D. A line width X1 of a copper wire 1301 between one of the two side columns 123D of a circuit board 130D and the center column 122D is equal to a line width X2 of a copper wire 1302 between the other of the two side columns 123D and the center column 122D.

Referring to FIG. 9, a line width X3 of a copper line 1303 of a circuit board 130E is equal to a line width X4 of a copper line 1304, and a line width X5 of a copper line 1305 is equal to a line width X6 of a copper line 1306. Here, the line width X3 may be equal to or different from the line width X6, and the invention is not limited thereto.

Based on the above, in the inductor wiring structure of the invention, there are a first space and a second space respectively between the center column and the two side columns, the first wiring at least passes through the first space to surround the center column, and the second wiring only passes through the second space to surround the center column. Thereby, the total number of windings formed by the inductor wiring at the first space is equal to the total number of windings formed by the inductor wiring at the second space, to achieve maintaining a relatively uniform flux distribution of the magnetic core, avoiding core flux imbalance, effectively reducing the winding loss of the copper wire, and effectively reducing overall volume. In an embodiment, the inductor wiring structure may also be designed as a planar inductor by means of PCB wiring.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. An inductor wiring structure, comprising:
an inductor wiring having an input end and an output end, and comprising a first wiring connected to the input end and a second wiring connected to the output end; and
a core member magnetically coupled to the inductor wiring, wherein the core member comprises a base, a center column protruded beyond the base, and two side columns, there is a first space and a second space respectively between the center column and the two side columns, the first wiring at least passes through the first space to surround the center column, and the second wiring passes through the second space to surround the center column, wherein a number of times the inductor wiring passes through the first space is equal to a number of times the inductor wiring passes through the second space.

2. The inductor wiring structure of claim 1, wherein a cross-sectional area of
the center column is greater than a cross-sectional area of each of the side columns.

3. The inductor wiring structure of claim 1, wherein the first wiring has a first end away from the input end, the second wiring has a second end away from the output end, the input end and the output end are located at a side of the core member, and the first end and the second end are located at another side of the core member.

4. The inductor wiring structure of claim 3, wherein the center column comprises an upper sidewall and a lower sidewall symmetrically divided by a center of the center column, the upper sidewall corresponds to the first space, the lower sidewall corresponds to the second space, there is a first winding segment between the input end and the first end, the first winding segment is wound around the upper sidewall of the
center column, there is a second winding segment between the output end and the second end, and the second winding segment is wound around the lower sidewall of the center column.

5. The inductor wiring structure of claim 3, wherein the center column
comprises an upper sidewall and a lower sidewall symmetrically divided by a center of the center column, the upper sidewall corresponds to the first space, the lower sidewall corresponds to the second space, there is a first winding segment between the input end and the first end, the first winding segment is wound around the upper sidewall and the lower sidewall of the center column, a number of times the first winding segment passes through the upper sidewall is N, a number of times the first winding segment passes through the lower sidewall is N- I there is a second winding segment between the output end and the second end, the second winding segment is wound around the lower sidewall of the center column, and a number of times the second winding segment passes through the lower sidewall is 1.

6. The inductor wiring structure of claim 3, wherein the first end and the second end are used to connect a transformer.

7. The inductor wiring structure of claim 6, wherein the two side columns are arranged in a first direction, and an extending direction of a primary side coil of the transformer and an extending direction of a secondary side coil of the transformer are
parallel to the first direction.

8. An inductor wiring structure, comprising:
an inductor wiring having an input end and an output end, and comprising a first wiring connected to the input end and a second wiring connected to the output end;
a core member magnetically coupled to the inductor wiring, and the core
member comprises a base, a center column protruded beyond the base, and two side columns, there is a first space and a second space respectively between the center column and the two side columns, the first wiring at least passes through the first space to surround the center column, and the second wiring passes through the second space to surround the center column, wherein a number of times the inductor wiring passes through the first space is equal to a number of times the inductor wiring passes through the second space; and
a circuit board, wherein the inductor wiring is formed at the circuit board, and the center column passes through a through hole of the circuit board.

9. The inductor wiring structure of claim 8, wherein a cross-sectional area of the center column is greater than a cross-sectional area of each of the side columns.

10. The inductor wiring structure of claim 8, wherein the first wiring has a first end away from the input end, the second wiring has a second end away from the output end, the input end and the output end are located at a side of the core member, and the first end and the second end are located at another side of the core member.

11. The inductor wiring structure of claim 10, wherein the circuit board is a single-layer board, the center column comprises an upper sidewall and a lower sidewall symmetrically divided by a center of the center column, the upper sidewall corresponds to the first space, the lower sidewall corresponds to the second space, there is a first
winding segment between the input end and the first end, the first winding segment is wound around the upper sidewall of the center column, there is a second winding segment between the output end and the second end, and the second winding segment is wound around the lower sidewall of the center column.

12. The inductor wiring structure of claim 10, wherein the circuit board is a
multi-layer board, the center column comprises an upper sidewall and a lower sidewall symmetrically divided by a center of the center column, the upper sidewall corresponds to the first space, the lower sidewall corresponds to the second space, there is a first winding segment between the input end and the first end, the first winding segment is
wound around the upper sidewall and the lower sidewall of the center column, a number of times the first winding segment passes through the upper sidewall is N, a number of times the first winding segment passes through the lower sidewall is N-1 there is a second winding segment between the output end and the second end, the second winding segment is wound around the lower sidewall of the center column, and a number of times the second winding segment passes through the lower sidewall is 1.

13. The inductor wiring structure of claim 12, wherein the circuit board comprises a first layer board and a second layer board, a conductive structure is provided between the first layer board and the second layer board, the first winding segment comprises a first section and a second section, the first section is located at the first layer
board, the second section is located at the second layer board, the first section completely surrounds the upper sidewall and the lower sidewall of the center column and is electrically connected to the second section via the conductive structure, and the second section is wound around the upper sidewall.

14. The inductor wiring structure of claim 13, wherein the second winding
segment is located at the second layer board.

15. The inductor wiring structure of claim 10, wherein the first end and the second end are used to connect a transformer.

16. The inductor wiring structure of claim 15, wherein the two side columns are arranged in a first direction, and an extending direction of a primary side coil of the
transformer and an extending direction of a secondary side coil of the transformer are parallel to the first direction.

17. A magnetic component, comprising:
a wiring having a first wiring and a second wiring; and
a core member comprising a base, an upper cover, a center column, a first side column, and a second side column, wherein the center column, the first side column and the second side column are disposed between the base and the upper cover, and the center column is located between the first side column and the second side column;
wherein the first wiring passes through between the center column and the first side column, the second wiring passes through between the center column and the second side column, and the first wiring and the second wiring are not in contact with each other.

18. The magnetic component of claim 17, further comprising:
a third wiring passing between the center column and the first side column and passing between the center column and the second side column; and
a conductive structure connected to the third wiring and the first wiring.

19. The magnetic component of claim 17, wherein there is a first spacing, a second spacing, and a third spacing between the first wiring and the second wiring, the first spacing is greater than the second spacing, and the second spacing is greater than or equal to the third spacing.
